(19) United States
(12) Patent Application Publication
(10) Pub. No.: US 2005/0061673 A1
(43) Pub. Date: Mar. 24, 2005

(54) Capillary electrophoresis mass spectrometry interface

(76) Inventors: Katja B. Presto Elgstoen, Oslo (NO); Daniel Nybo, Raholt (NO)

Correspondence Address: MAINE & ASMUS, 100 MAIN STREET, P O BOX 3445, NASHUA, NH, 03061-3445, US

(21) Appl. No.: 10/494,904

(22) PCT Filed: Nov. 8, 2002
(86) PCT No.: PCT/NO02/00411

(30) Foreign Application Priority Data
Nov. 8, 2001 (NO) 20015470

(51) Int. Cl. G01R 1/00; C02F 1/40

(52) U.S. Cl. 204/601; 204/604

(57) ABSTRACT

A device for connecting a capillary (5) for capillary electrophoresis (CE) to an ionisation source (11) in an apparatus for mass spectrometry (MS) (12) is described, the device comprising a chamber (7) for an electrolyte, which chamber (7) has a first inlet (17) for the capillary (5) and a second inlet (16) for the electrolyte from a reservoir (8) and an outlet (17) for the capillary (5), where a tubular electrode (10) through which the capillary is passed, is arranged in connection to the outlet (17), and through which electrode (10) the electrolyte may flow around the capillary (5), wherein a flow chamber (31, 36) is arranged upstream for the electrode (10) in which flow chamber (31, 36) an electrically conducting surface electrically connected to the electrode (10), is arranged. Additionally, a system for analysis comprising said device for connecting is described.

The present invention regards a device for connecting capillary electrophoresis (CE) and a mass spectrometer (MS), as well as a system for analysis of a of a sample solution, which system comprises an apparatus for CE and MS.

### BACKGROUND ART

Electrophoresis is a technique by which ions dissolved in an electrolyte solution may be separated on the basis of their migration in an electric field. The ions move at different speeds in the electric field, depending on the ratio between mass and charge. Capillary electrophoresis is an electrophoresis technique that allows efficient separation of small amounts of material, with the separation taking place in a quartz tube.

A mass spectrometer (MS) measures the mass to charge ratio of molecules and molecular fragments in the gaseous phase. In the case of liquid samples, the liquid must be evaporated or atomized and the sample molecules must be converted to ions in the gaseous phase prior to mass analysis. Electrostatic spraying (electrospray) ionization is the most commonly used ionization technique for this purpose.

The mass analyser in an MS may be constructed in several ways, with the most common being the quadrupole technique. Combining two quadrupoles with a collision chamber in between gives what is called a triple quadrupole or an MS/MS.

With an MS/MS, it is possible to obtain structural information regarding the sample molecules, which in turn makes reliable identification possible. The first MS gives the molecular weight; A large surplus of energy is then introduced to the molecule in the collision chamber, and the mass fragments thus formed are then mass analysed in MS number 2.

In certain cases therefore, MS/MS can replace another separation technique combined with a single MS. Still, in many cases, especially for the analysis of complex solutions such as biological materials, temporal separation is required prior to introducing the materials into the ion source.

By coupling capillary electrophoresis (CE) with MS or MS/MS, the components of the samples will first be separated temporally from their charge/mass in CE, whereupon the single components are mass analysed to provide structural information and consequently identification.

Coupling of CE and MS or MS/MS is known, and has been described in the literature. Standard ion sources for electrospray ionization may be connected to CE. However, this gives rise to a number of practical problems that make this technique relatively unsuitable in practice. The greatest problem is heat generation between the individual components due to a high current density. This causes heating of the CE capillary, which will then easily burn and break off in the ion source. The capillary must then be replaced in an extensive operation that involves disconnection and then reconnection of all connections. Another problem is the relative impracticality of the existing solutions. Long CE capillaries must be used in order to allow interconnection, which in turn leads to long analysis times. The rather impractical interconnection is due to the fact that the capillary and the so-called sheath liquid that surrounds the capillary have to go via an earthing point on the way from the spray pump to the ion source. This is done to prevent operators from receiving shocks when touching the syringe containing sheath liquid in the spray pump. The positioning of the earthing point on the ion source makes it necessary to bend the capillary quite steeply, which in turn makes it easy to break. Also, the connections will tend to come apart, causing leakage.

J. Fred Banks, Electrophoresis, vol. 18, (1997), pages 2255-2266, Recent advances in capillary electrophoresis/electrospray/mass spectrometry provides a good summary of the principles of coupling CE and MS. This general article deals with the general theory and practical considerations involved in the known methods of coupling capillary electrophoresis and mass spectrometry (CE-MS). Banks describes CE-MS as a technique of “potentially challenging instrumental aspects”, and goes a long way in explaining why this is the case:

In normal CE analysis, there are inlet and outlet buffer reservoirs where the capillary passes from one reservoir to the other, and where the two reservoirs are tied in to an electric circuit through an electrode being arranged in each glass. In the case of CE-MS, there is no outlet buffer reservoir. Therefore, a means of electrical contact between the liquid in the capillary and an electrode in the MS (earth) must be provided. In order for the CE-MS to function, the liquid entering the MS ion source must also have certain properties such as low ionic strength, low surface tension etc. The geometrical shape of the components inside the ion source is also of great significance. Banks goes on to describe how, based on these considerations, four different so-called interfaces have been developed for CE connected to MS:

a) Sheath Flow:

This is the most commonly used method. The capillary from CE is here led into the ion source by being located inside a metal tube that delivers sheath liquid to the outlet of the CE capillary in the ion source. Sheath liquid mixes with the liquid from the capillary, establishing electrical contact between the metal tube and the liquid in the capillary. The advantage of this technique is that one may select a sheath liquid with properties that renders the ionized solution more suitable for MS analysis.

b) Sheathless Approach:

Here the capillary is heated and stretched out to a fine point. The outside of the capillary is then coated in a metal coating connected to earth via an electric line. A sheath gas, preferably SF₆, is used to remove the surplus of electrons that arises with the use of this type of interface. Not commercially available.

c) Liquid Junction:

The CE capillary is placed in a tee coupler with a small dead volume. A liquid connected to earth is introduced into the tee coupler. This liquid is mixed with the liquid from the CE capillary, and the mixture is carried up to the spray tip, which may be made of metal or silica. The technique is considered difficult to carry out.

d) Direct Electrode:

Here a thin gold electrode pin is placed into the opening of the CE capillary inside the ion source. It is crucial that the electrode be positioned in exactly the correct position. Not commercially available.

Maria A. Petersson, Gustaf Hulthe, Elisabet Fogelquist, Journal of Chromatography A, vol. 854 (1999), pages 141-154, “New sheathless interface for coupling capillary electrophoresis to electrospray mass spectrometry evaluated by the analysis of fatty acids and prostaglandins” provides an overview of several methods of creating an interface where the CE capillary is positioned inside of and in close (distance 0-100 microns) contact with a metal tube connected to earth. The methods described therein are according to alternative b) above. No sheath liquid is used, but both the metal tube and the capillary are shaped in a manner that allows them to be positioned in such close proximity to each other as to give rise to a thin liquid solution film in the capillary between the capillary and the metal tube. The CE capillary is heated and stretched out to a fine point, as is the metal tube. The authors refer to good results for the analysis of fatty acids and prostaglandins. The set-up they use is not commercially available. The authors report a variable quality of the CE capillaries and the metal tubes that are formed. It requires a lot of experience and not least special devices to create such an interface. The article illustrates the fact that the system is of little practical use, although the interface principle is a good one.

Interface type a) above, sheath flow, is definitely the simplest coupling technique, as it allows already existing standard ion sources for electrospray to be used as a basis.

Thus the object of the present invention is to provide coupling between capillary electrophoresis and mass spectrometry, primarily according to the sheath flow method (interface a) above), whereby the above problems are avoided.

### SUMMARY OF THE INVENTION

According to a first aspect of the present invention, a device is provided for connecting a capillary for capillary electrophoresis (CE) to an ion source in an apparatus for mass spectrometry (MS), comprising a chamber for an electrolyte, where the chamber has a first inlet for the capillary and a second inlet for electrolyte from a reservoir, as well as an outlet for the capillary, in connection with which outlet there is provided a tubular electrode through which the capillary extends, and through which electrode the electrolyte may flow out around the capillary, a flow chamber being provided for the electrolyte upstream of the electrode, in which flow chamber there is provided an electrically conductive surface in electrical contact with the electrode.

According to a preferred embodiment, the electrically conductive surface is constituted by the walls of the flow chamber.

Preferably, the inlets are inlets in a tee coupler, and the chamber is a hose that encloses the capillary from the tee coupler to the flow chamber.

According to a preferred embodiment, the device further comprises a connection, where the connection comprises an outer screw with a bore through which the hose and the capillary can run, as well as an outer fixing screw for fastening the hose to the outer screw and an inner fixing screw for fastening the tubular electrode to the outer screw, and where the capillary between the outer and inner fixing screws pass from the interior of the hose to the interior of the electrode, and where a flow chamber is provided in the connection, which flow chamber has walls made from an electrically conductive material, through which flow chamber the electrolyte from the hose may flow after issuing from the hose, prior to flowing through the electrode.

For the latter preferred device, the flow chamber is preferably situated between the inner and outer fixing screws.

Preferably, the flow chamber is a bore in a connecting piece matched to the inner fixing screw.

Preferably, the flow chamber has a diameter that is at least the same as the internal diameter of the hose.

Preferably also, the flow chamber has a length that is at least the same as the internal diameter of the hose.

According to a second aspect of the present invention, a system is provided for carrying out an analysis of a sample solution, comprising an apparatus for capillary electrophoresis (CE) and an apparatus for mass spectrometry (MS), comprising a beaker for the sample solution with-a first electrode and a capillary running from the beaker to a second, tubular electrode in an ionization chamber in the MS apparatus, where a chamber is provided for an electrolyte, where the chamber has a first inlet for the capillary and a second inlet for electrolyte from a pump, as well as an outlet for the capillary, where the tubular electrode is arranged in connection to the outlet and where the capillary runs through the electrode, and where the electrolyte can flow through the electrode around the capillary, where a flow chamber is provided for the electrolyte upstream of the electrode, in which flow chamber there is provided an electrically conductive surface in electrical contact with the electrode.

Preferably, the electrically conductive surface is made up of the walls of the flow chamber.

It is furthermore preferable for the inlets to be inlets in a tee coupler and the chamber to be a hose surrounding the capillary from the tee coupler to the flow chamber.

According to a preferred embodiment, the system further comprises a connection, where the connection comprises an outer screw having a bore through which the hose and the capillary may run, as well as an outer fixing screw for fastening the hose to the outer screw and an inner fixing screw for fastening the tubular electrode to the outer screw, and where the capillary between the outer and the inner fixing screws passes from the interior of the hose to the interior of the electrode, and where a flow chamber is provided in the connection, which flow chamber has walls made from an electrically conductive material, through which flow chamber the electrolyte from the hose may flow after issuing from the hose and before flowing through the electrode.

Preferably also, the flow chamber is situated between the inner and outer fixing screws.

It is furthermore preferable for the flow chamber to be a bore in a connecting piece matched to the inner fixing screw.

Preferably also, the flow chamber has a diameter that is at least the same as the internal diameter of the hose.

Preferably, the flow chamber is of a length that is at least the same as the internal diameter of the hose.

### SHORT DESCRIPTION OF THE DRAWINGS

FIG. 1 shows a schematic diagram for coupling of CE-MS/MS;

FIG. 2 shows a more detailed schematic diagram for coupling of CE-MS/MS according to prior art;

FIG. 3 shows a preferred embodiment of a coupling according to the present invention;

FIG. 4 shows another preferred embodiment of a coupling according to the present invention;

FIG. 5a shows a standard electrode with means for insertion into an MS apparatus; and;

FIG. 5b shows an electrode with modified means for insertion into an MS apparatus.

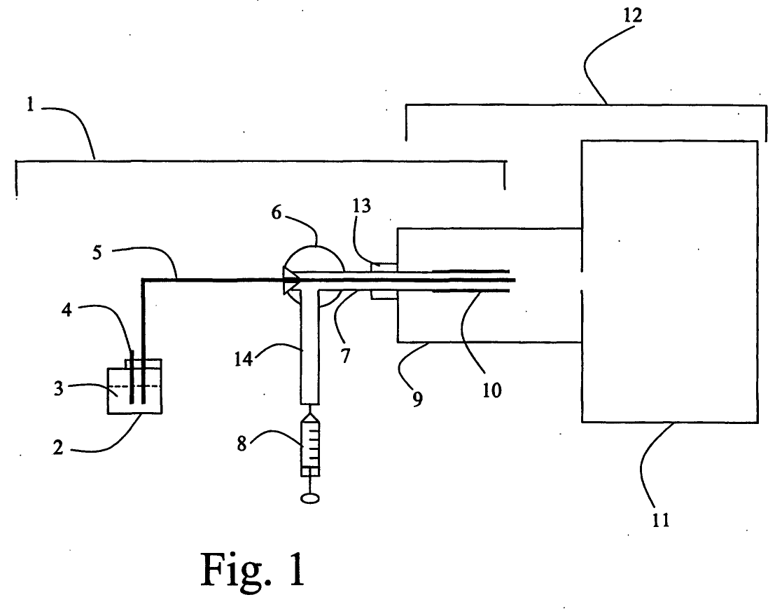

FIG. 1 is a schematic diagram for coupling of CE-MS/MS according to the sheath flow principle a) described above. The drawing shows a CE apparatus 1 and an MS/MS apparatus 12, as well as means 6 for coupling these.

The CE apparatus 1 comprises a beaker 2 for an electrolyte 3, a first electrode 4, a capillary 5 and a second, tubular electrode 10. The capillary 5 runs from the beaker 2 and into the MS/MS apparatus 12 via the coupling means, typically a tee coupler 6. The capillary 5, which normally has an internal diameter of 25-100 microns, extends through the tee coupler 6 and into an ion source 9 in the MS/MS apparatus 12.

Inside the ion source 9, the capillary 5 extends through a tubular electrode 10. A voltage source (not shown) is connected in between the electrodes 4 and 10, generating the electric field that causes ion migration and separation in the CE apparatus. The voltage between the electrodes 4, 10 may be of the order of 10 000-50000 volts, for example around 25000 volts.

In the tee coupler 6, the capillary enters through a first inlet 15 and exits the tee coupler 6 surrounded by a chamber 7 filled with electrolyte. Preferably, the chamber 7 is a hose 7. The hose 7 is filled with an electrolyte that surrounds the capillary in the entire area from the first inlet 15 and into the MS-MS apparatus through a coupling 13.

The electrolyte in the hose 7 also acts as a conductor between the electrode 10 and the fluid in the capillary inside the ion source. The electrolyte in the hose 7 is filled and refilled from a reservoir 8 via a feed hose 14 running from the reservoir 8 to a second inlet 16 into the tee coupler 6. The reservoir 8 may be a pressurised reservoir-such as e.g. a syringe, or it may be connected to a pump (not shown) that pumps a controlled volume of electrolyte through the hose 14 to the tee coupler 6.

The hoses 7 are made from an inert, electrically insulating material, commonly a plastic material such as e.g. PEEK (polyether-etherketone).

The electrolyte in the capillary is ionized in the ion source 9 by a liquid mixture containing the electrolyte in which the sample is dissolved and the electrolyte in the hose 7 being sprayed out of the electrode 10, where a potential of typically 5000 volts exists between the electrode 10 and the body of the ionizing apparatus. Thus the electrode 10 has a dual function, both as an electrode in the CE apparatus and as an electrode in the MS apparatus. The ionized sample is then analysed in the MS/MS apparatus 11 in a known manner.

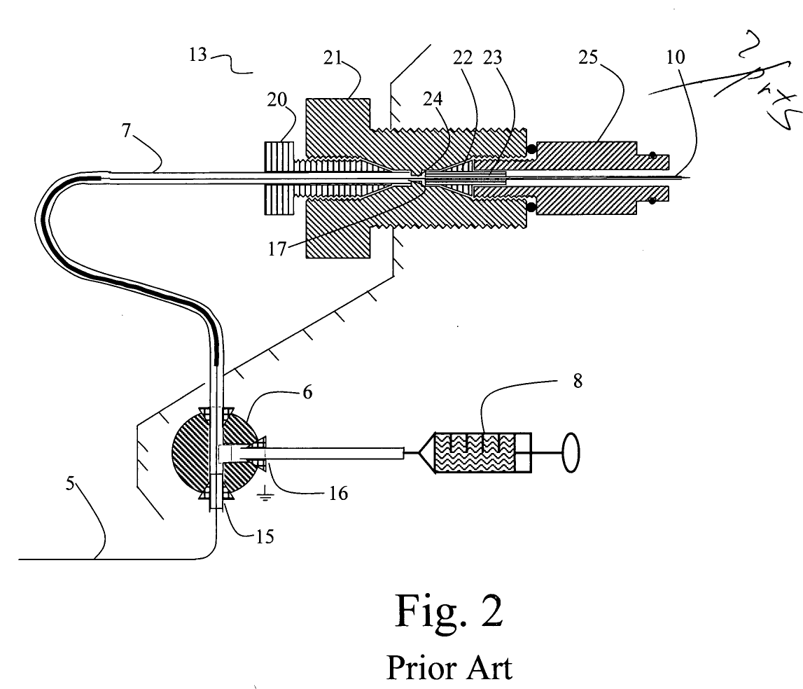

It is the actual coupling between the capillary electrophoresis and the MS/MS apparatus which constitutes the problem solved by the present invention. FIG. 2 shows an example of a standard coupling between these apparatuses such as delivered from a major supplier in the market.

The coupling 13 normally comprises an outer screw 21 made from a plastic material such as PEEK, which is screwed into the body of the MS-MS apparatus, a fixing screw 20 for fastening the hose 7 to the coupling 13, and an inner fixing screw 25 for fixing the electrode 10 in the coupling 13. In addition to providing a fastening means for the leadthrough into the MS apparatus, the outer screw 21 must also prevent galvanic contact between the body of the MS apparatus and the electrode.

The connection between the electrode 10 and the coupling 13 comprises a bushing 22 that surrounds one end of the electrode, as well as a plastic liner 23 that surrounds the electrode 10 and provides a seal between this and the inner fixing screw 25. The bushing 22 is conical, and is matched to a conical recess in the outer screw 21 in a manner such that it squeezes around the electrode 10 when the fixing screw 25 is tightened.

A transition area 24 is defined between the outer fixing screw 20 and the inner fixing screw 25 inside the outer screw 21, in which area the electrolyte in the hose 7 ends in an outlet 17 where the electrolyte runs into the interior of the electrode 10. In practice, the distance between the outlet 17 from the hose 7 and the electrode 10 with bushing 22, i.e. the transition area 24, is very small, e.g. 500 microns in diameter and 800 microns in length.

It is precisely the transition between the hose 7 and the electrode 10 that is the origin of the coupling problems. The capillary 5 is heated intensely in this area, as the current density is very high around the capillary at the point where this passes from the interior of the hose to the interior of the electrode 10. Therefore, the capillary 5 burns off after a very short running time

Another problem associated with the existing solutions is that the assembly of the apparatuses has depended on the capillary being bent extensively to pass via the earthing point. Moreover, the capillary is assumed to have a certain minimum length, as the path into the apparatus via today's tee coupler solution is long.

In the assembly of these apparatuses which has been used up to the present, the parts of the coupling 13 have, as mentioned above, been executed in an electrically insulating material such as plastic, leaving only the electrode 10 in an electrically conductive material.

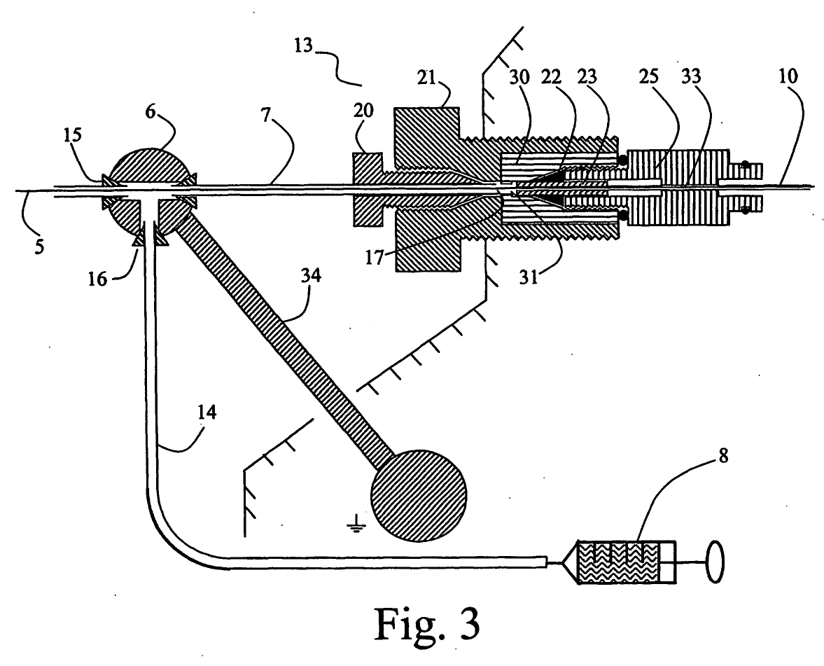

FIG. 3 shows a first preferred assembly according to the present invention. The tee coupler has here been mounted on a bracket 34 executed in an electrically conductive material such as metal. It is important for the tee coupler 6 to be in electrical contact with the earthed body of the MS-MS apparatus, indicated by an earth symbol in the drawing.

The bracket 34 with the tee coupler 6 has been arranged so as to give the capillary 5 the straightest possible path from the CE apparatus to the MS-MS apparatus. The bracket 34 is electrically conductive and has been connected to the MS apparatus earth. This is vital in order for the residual current, which also plays a part in burning the capillary, to go to earth, as well as in safeguarding the operating personnel against electrical shocks when touching the apparatus and the reservoir 8, e.g. in connection with refilling.

The outer screw 21 has been modified so as to consist of an outer part made of an electrically insulating material such as plastic, for fastening the fixing screw 20, and an inner part 30 made from an electrically conductive material such as metal, for fastening the connecting screw 25 and the electrode 10.

According to the present invention, the inner fixing screw 25 is also manufactured from an electrically conductive material such as metal. This can be achieved either by giving the fixing screw 25 an internal bore having such a small diameter as to bring the electrode 10 into contact with the walls when disposed inside of this, or by a set screw in the inner fixing screw 25 pressing the electrode against the fixing screw 25 so as to establish electrical contact. A person skilled in the art will also be able to identify other means of ensuring electrical contact between the electrode 10 and the fixing screw 25.

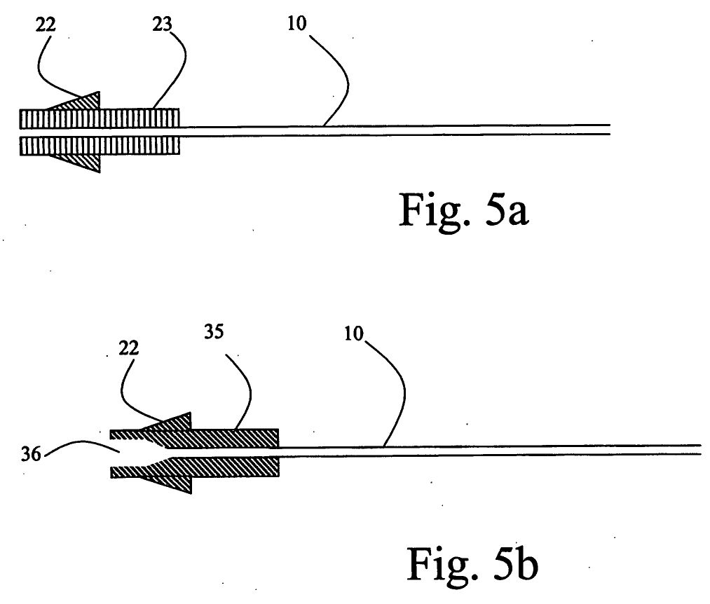

Preferably, the outer fixing screw 20 has a conical end matched to a corresponding conical recess in the outer screw 21. The inner fixing screw 25 is adapted to be screwed into the inner part 30 of the outer screw 21 for fastening of the electrode 10 with bushing 22. The electrode 10 with bushing 22 and liner 23 is essentially equivalent to a standard electrode such as delivered from one of the major suppliers of such equipment, and which is also shown in FIG. 5a. Preferably, the bushing 22 is conical and matched to a corresponding conical recess in the inner part 30.

However, according to this embodiment, a flow chamber 31 is provided between the bores for fastening of the fixing screws 20, 25 and the electrode 10 with the bushing 22. Preferably, this flow chamber 31 has a diameter greater than or equal to the internal diameter of the plastic hose 7 and a length greater than or equal to the internal diameter of the hose. A commonly used hose has an internal diameter of 1 mm. In this case, the length should be 1 mm or more. However, it is also possible for the flow chamber 31 to have a diameter that differs from the internal diameter of the hose 7. Still, the most important thing is that the flow chamber is sufficiently long and has a large enough diameter to achieve a volume of liquid around the capillary inside the flow chamber 31 such that the current density in this area is prevented from becoming high enough to cause heating of the capillary, causing this to bum off.

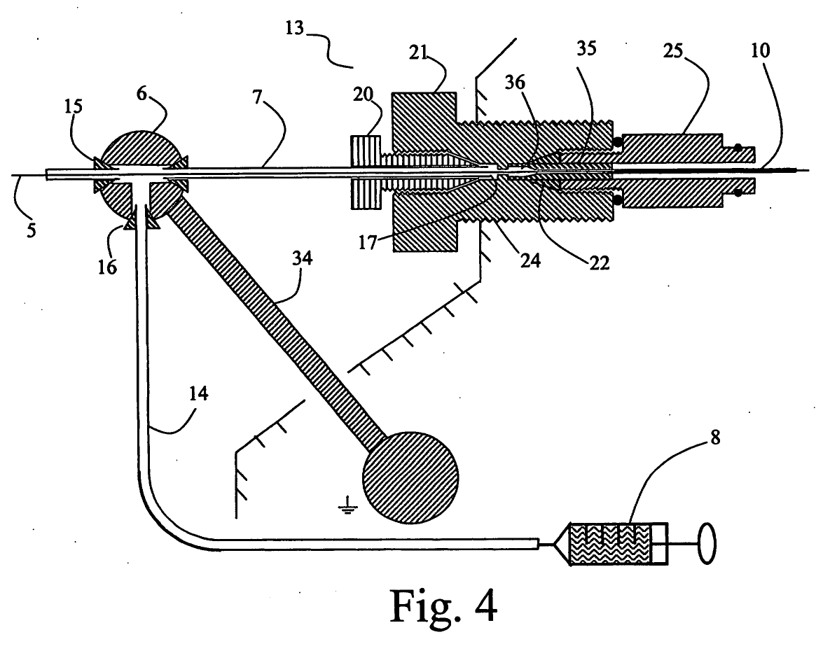

FIG. 4 shows an alternative preferred embodiment of the present invention in which use is made of en electrode 10 having a connecting piece 35 and a bushing 22 as described above. As described above, the connecting piece 35 and the bushing 22 are adapted for engagement with the outer screw 21. Optionally, the connecting piece 35 and the bushing 22 may be constructed all in one piece. The connecting piece 35 has an approximately cylindrical shape and a bore 36 that in the main extends into one end of the connecting piece in an axial direction. At the other end, the electrode 10 is attached, also in an approximately axial orientation relative to the longitudinal axis of the connecting piece. Preferably, the connecting piece 35 is manufactured in one piece and made from an electrically conductive material such as metal, and is connected directly to the electrode 10. Alternatively, the connecting piece 35 may be made from a non-conductive material and the inner surface of the inner bore 36 may be lined with a conductive material in electrical contact with the electrode 10.

The inner bore 36 provides an inner chamber in the connecting piece, which gives a large area of contact between the electrically conductive connecting piece and the electrolyte issuing from the hose. Thus the inner bore 36 acts as the above flow chamber 31. This embodiment of the present invention allows the same advantages to be achieved as those listed for the first embodiment, even when using a standard coupling 13 in which the electrode 10 with the liner 23 and the bushing 22 is replaced by a modified version with a connecting piece 35 made from an electrically conductive material. This makes it possible to reduce the heat generation caused by a high current density at the transition between the hose 7 and the electrode 10.

It has proven advantageous for the inside edge of the bore opening to be bevelled, so as to avoid densification of current.

However, the connecting piece 35 is more complicated to manufacture than a modified coupling 13 such as described in the first embodiment, and the choice of embodiment in a given situation is dependent on financial and practical parameters.

Those skilled in the art will be able to envisage solutions that are analogue to the above described preferred embodiments, which solutions will clearly lie within the scope of the appended claims. As an example, the connecting piece 13 may be constructed in an entirely different manner, e.g. by replacing the threads for fixing the connecting piece between the outer 20 and inner 21 fixing screws respectively, with other connecting means such as e.g. a bayonet coupling, or it may be held together by clasps or similar.

Likewise, it is clear that the chamber 7 may have a different shape from that of a hose such as described in the present specification. For practical reasons, it is often appropriate to use a hose, but the chamber 7 may also have another physical shape. For instance, a chamber may conceivably be integrated with the connecting piece 13, where an internal tee coupler ensures that the capillary gets into the apparatus, and also provides the supply of electrolyte.

In the figures, the reservoir 8 has been represented by a syringe. It may be appropriate for the reservoir to be a syringe, but it may also have a different form. Preferably, the electrolyte is fed to the chamber 7 at a certain pressure so as to actively inject electrolyte to replace that which has been lost out through the electrode 10. The reservoir may therefore be a syringe, optionally placed in a pump in order to provide a constant supply of liquid, it may be a pressurised container, or it may be a container connected to a pump.

In the above described embodiments, the walls of the flow chamber 31, 37 are electrically conductive and in contact with the electrode 10. However, it is also possible for the walls of the flow chamber not to be electrically conductive, and for another electrically conductive surface to be provided in the flow chamber, which surface is in electrical contact with the electrode 10.

### CALCULATION EXAMPLES

As mentioned above, the problem of burning off the capillary is caused by heating due to a high current density in the area where the current passes between the metal electrode 10 and the liquid in the transition area 24. The effect generated in a volume will be as follows:
P/V=ρ* J², where P is the effect, V is the volume, ρ is the resistance of the material, given in e.g. ohm/m, and J is the current density, given in e.g. mA/cm². Thus the effect generated per volume of liquid will increase by a power of two with current density.

### SOLUTION ACCORDING TO PRIOR ART

In the previously known standard solution, the CE capillary 5 running through the electrode 10 takes up virtually the entire diameter of this. Thus the area of this standard solution which is available for conductive connection is limited to the end face of the electrode 10 where this passes into the interior 24 of the fixing screw 21. Therefore, the conductive connection area is as follows:
A=Π*(the external diameter of the metal electrode)²−(the internal diameter of the metal electrode)²=Π*(0.155²−0.100²)=0.044 mm²

In addition, the conductive connection here takes place at a very small distance from the capillary where this goes into the electrode 10.

### SOLUTION ACCORDING TO THE PRESENT INVENTION

In the device according to the present invention, the entire internal area of the flow chamber 31 will be available for conductive contact. In the prototype used in the research, the flow chamber 31 is cylindrical, and both the length and the diameter is 1 mm. As the internal volume of the flow chamber 31 is partially filled by a non-conductive capillary, this must be compensated for in the calculation of the effective area for conductive connection. Consequently, the area for conductive connection in the flow chamber 31 will be (the area of contact against the end face of the metal electrode as in the above solution, is so small as to be left out):

$$Area of conductive connection = circumference ( 31 ) * length ( 31 ) = \prod * diameter ( 31 ) * ( diameter ( 31 ) - diameter ( capillary ) ) == \prod * 1 mm * ( 1 mm - 0.18 mm ) = \prod * 1 mm * 0.82 mm = 2.75 {mm}^{2}$$

This increases the area of conductive connection by 2.75 mm²/0.044 mm²≈60. Based on the above formula for generation of effect per volume of liquid, this reduces the generated effect by 60², or 3600, times. This drastic reduction of the generated effect will eliminate or at least lead to a strong reduction of the risk of capillary burn-off.

1. A device for connecting a capillary for capillary electrophoresis (CE) to an ion source in an apparatus for mass spectrometry (MS), comprising a chamber for an electrolyte, where the chamber has a first inlet for the capillary and a second inlet for electrolyte from a reservoir, as well as an outlet for the capillary, in connection with which outlet there is provided a tubular electrode through which the capillary runs, and through which electrode the electrolyte can flow out around the capillary, wherein a flow chamber is provided for the electrolyte upstream of the electrode, in which flow chamber there is disposed an electrically conductive surface in electrical contact with the electrode.

2. A device according to claim 1, wherein the electrically conductive surface is constituted by the walls of the flow chamber.

3. A device according to claim 1, wherein the inlets are inlets to a tee coupler and the chamber is a hose surrounding the capillary from the tee coupler to the flow space.

4. A device according to claim 1, wherein the device further comprises a coupling comprising an outer screw having a bore through which the hose and the capillary may run, as well as an outer fixing screw for fastening the hose to the outer screw and an inner fixing screw for fastening the tubular electrode to the outer screw, and where the capillary between the outer and inner fixing screws passes from the interior of the hose to the interior of the electrode, and where a flow chamber is provided in the coupling, with walls made from an electrically conductive material, through which flow chamber the electrolyte from the hose may flow after issuing from the hose and before flowing through the electrode.

5. A device according to claim 4, wherein the flow chamber is situated between the inner and outer fixing screws.

6. A device according to claim 4, wherein the flow chamber is a bore in a connecting piece matched to the inner fixing screw.

7. A device according to claims 4, wherein the diameter of the flow chamber is greater than or equal to the internal diameter of the hose.

8. A device according to claim 7, wherein the length of the flow chamber is greater than or equal to the internal diameter of the hose.

9. A system for performing an analysis of a sample solution, comprising an apparatus for capillary electrophoresis (CE) and an apparatus for mass spectrometry (MS), comprising a beaker for the sample solution with a first electrode and a capillary running from the beaker to a second, tubular electrode in an ionization chamber in the MS apparatus, wherein a chamber is provided for an electrolyte, the chamber having a first inlet for the capillary and a second inlet for electrolyte from a pump, as well as an outlet for the capillary, where the tubular electrode is arranged in connection with the outlet and where the capillary runs through the electrode, and where the electrolyte can flow through the electrode around the capillary, where a flow chamber is provided for the electrolyte upstream of the electrode, in which flow chamber there is provided an electrically conductive surface in electrical contact with the electrode.

10. A system according to claim 9, wherein the electrically conductive surface is constituted by the walls of the flow chamber.

11. A system according to claim 9, wherein the inlets are inlets into a tee coupler and the chamber is a hose surrounding the capillary from the tee coupler to the flow chamber.

12. A system according to claim 9, wherein the system further comprises a coupling comprising an outer screw having a bore through which the hose and the capillary can pass, as well as an outer fixing screw for fastening the hose to the outer screw and an inner fixing screw for fastening the tubular electrode to the outer screw, and where the capillary between the outer and the inner fixing screws pass from the interior of the hose to the interior of the electrode, and where a flow chamber having walls made from an electrically conductive material is provided in the coupling, through which flow chamber the electrolyte from the hose may flow after issuing from the hose and before flowing through the electrode.

13. A system according to claim 12, wherein the flow chamber is situated between the inner and outer fixing screws.

14. A system according to claim 12, wherein the flow chamber is a bore in a connecting piece matched to the inner fixing screw.

15. A system according to claims 12, wherein the diameter of the flow chamber is greater than or equal to the internal diameter of the hose.

16. A system according to claim 15, wherein the length of the flow chamber is greater than or equal to the internal diameter of the hose.
